(19) United States
(12) Patent Application Publication
(10) Pub. No.: US 2008/0066888 A1
(43) Pub. Date: Mar. 20, 2008

(54) HEAT SINK

(75) Inventors: Wei Tong, Radford, VA (US); John Boyland, Christiansburg, VA (US)

Correspondence Address: HOLLAND & HART, LLP, P.O BOX 8749, DENVER, CO, 80201, US

(73) Assignee: Danaher Motion Stockholm AB, Stockholm (SE)

(21) Appl. No.: 11/530,237

(22) Filed: Sep. 8, 2006

(51) Int. Cl. H05K 7/20

(52) U.S. Cl. 165/80.3; 361/704

(57) ABSTRACT

A heat sink comprises a base panel having a top surface and a bottom surface. A plurality of pin fins extend outwardly from the top surface and each fin has a cross-sectional configuration with two radiuses, a first radius and a second radius, wherein the first radius is larger than the second radius. The first and second radiuses are tangentially interconnected by intermediate portions, giving the pin fin cross-sectional configuration a raindrop shape, thereby generating low pressure drop across the heat sink by minimizing the drag force effects and maintaining large exposed surface area available for heat transfer.

### FIELD OF INVENTION

The present invention relates to heat sinks in general, and more particularly, to pin fin heat sinks with improved structures for use in dissipating waste heat generated by electronic components and assemblies.

### BACKGROUND

The exponential increase in the power density of electronic components continues to fuel considerably interest in advanced thermal management of electronic equipment. The ability of an electronic device to maintain within a specific temperature region is directly related to the reliability and performance of the electronic device. Many electronic devices have strict temperature requirements for correct operation and performance. When an electronic component within a system overheats, often the entire electronic system is affected. Therefore, how to effectively dissipate the heat in a limited space to maintain the performance of the electronic devices becomes an important issue.

There are many techniques available to enhance heat dissipation from electronic components and devices.

Heat sinks are widely employed in electronic systems where space is limited. The use of passive natural convection cooled longitudinal straight plate-fin heat sinks offers substantial advantages in cost and reliability, but is often accompanied by relative low heat transfer rates. A conventional heat sink provided with longitudinal straight plate fins is depicted in FIG. 1. The heat sink comprises a plurality of extended straight fins that are used to enhance cooling of heat dissipating surfaces and a base plate that are used to conductively transport generated heat from a heat source to the fins. Each cooling channel is formed with adjacent straight plate fins. The plate fins are arranged parallel to the base normal line which is defined as the line along the base normal vector, i.e., perpendicular to the base surface.

Thus, by increasing the overall convective surface area exposed to a coolant, such as air and water, the rate of heat transfer is increased. However, because the width of the channels is the same, when cooling flow passes through these channels, the velocity profile is identical except at the flow inlet regions. This indicates that the thickness of the flow boundary remains a constant both along the channel and across the channels. More even, the heat transfer coefficient is also a constant.

The propensity of the heat sinks to create thermal turbulence is critical, because turbulent airflow increases the efficiency of the heat sinks and effectively increases the heat dissipated around an electronic component.

To further improve the thermal performance of heat sinks, an array of pin fins has been used to replace longitudinal straight plate fins, as shown in U.S. Pat. No. 6,343,016 to Lin. A pin fin heat sink generally consists of a base and a plurality of pin fins, see FIG. 2. The heat sink base provides the mounting frame for the fins. The base normal line is defined as the line along the base normal vector, i.e., perpendicular to the base surface.

Employment of such pin fins can result in better heat transfer characteristics because of the promotion of turbulence in the coolant passages between the pins and the additional surface made available. An array of pin fins may be provided in staggered rows on the base surface or may be in equally aligned rows on the base surface.

Pressure drop across a pin fin heat sink is one of the key variables that govern the thermal performance of the heat sink. In general, the total heat sink pressure drop depends on several design parameters and operation conditions, including: the pin fin geometry, the pin fin density and arrangement, the pin fin size, the heat sink orientation, and the approach velocity (only in forced convection). The design of heat sinks is intended to decrease the impedance of the fluid flow through the heat sink and, thereby, reduce pressure losses.

A further example of prior art heat sink is disclosed in U.S. Pat. No. 6,591,897 to Bhatti et al.

Thus, a problem in prior art pin fin heat sinks is to find an optimum configuration of the pin fins.

### SUMMARY OF THE INVENTION

An object of the present invention is to provide a heat sink of the kind initially mentioned, wherein the heat dissipation is improved as compared with prior art heat sink configurations. A particular object is to provide a heat sink with pin fins minimizing the pressure drop along the cooling flow path.

The invention is based on the insight that non-rectangular, such as rounded pin fins, produce less of a pressure drop than rectangular pin fins and particularly raindrop-shaped pin fins generate the lowest pressure drop across the heat sink by minimizing the drag force acting on fins and maintaining large exposed surface area available for heat transfer.

According to one aspect of the present invention there is provided a heat sink comprising a base panel having a top surface and a bottom surface; a plurality of pin fins extending outwardly from a said top surface of said base panel; each pin fin having a cross-sectional configuration with two radiuses, a first radius and a second radius, wherein the first radius is larger than the second radius; and wherein the first and second radiuses are tangentially interconnected by intermediate portions. This configuration gives the cross-section of each pin fin a raindrop shape, thereby generating low pressure drop across the heat sink by minimizing the drag force acting on fins and maintaining large exposed surface area available for heat transfer. If the intermediate portion are curved, the flow direction can be controlled.

In a preferred embodiment, the first larger radius is provided on the upstream portion of the pin fin.

In a preferred embodiment, the bases of the pin fins of the heat sink are rotated with respect to one another, where the rotation takes place in the plane containing the base of a particular heat sink. In other words, the symmetry lines of at least some of the pin fins are non-parallel with respect to one another. The net effect of the rotation of the bases of the heat sink and the elevation angle of the pins causes the flow of air across the surface of the pins to be disrupted. The increase in turbulent airflow over the heat sinks increases the efficiency of the heat sinks, providing a greater heat dissipation capability.

In a preferred embodiment, the heat sink base panel is contoured for enhancing heat transfer and to obtain more uniform temperature distribution. For instance, the profile of the top surface of the base panel can be sinusoidal along the cooling flow direction.

In a preferred embodiment, a plurality of air guide pin fins may be arranged at the sides of a plurality of fins for maximize the cooling flow rate and consequently increasing the heat dissipation efficiency of the heat sink; and/or in a plurality of fins for leading the cooling flow to the heat generation unit.

According to a second aspect of the present invention, a heat sink is provided comprising a base panel having a top surface and a bottom surface; a plurality of pin fins extending outwardly from a said top surface of said base panel; each fin consisting essentially of crescent moon-shaped cross-sectional profile, primarily configuring with two radiuses, wherein the center points of said two radiuses locating on the fin major axis.

Further preferred embodiments are defined by the dependent claims.

### BRIEF DESCRIPTION OF DRAWINGS

The invention is now described, by way of example, with reference to the accompanying drawings, in which:

FIG. 1 is a perspective view of a prior art heat sink with straight plate fins.

FIG. 2 is a perspective view of a prior art heat sink with pin fins.

FIG. 3 is a perspective view of a heat sink embodying the present invention with raindrop-shaped pin fins.

FIG. 4 is a schematic plan view of a raindrop pin fin.

FIG. 5 is a schematic plan view of a raindrop pin fin with a bending tail.

FIG. 6 shows the flow patterns between raindrop pin fins.

FIG. 7 shows the arrangement of air guide pin fins in a plurality of raindrop pin fins.

FIGS. 8A and 8B are numerical analysis results showing the thermal performance of conventional heat sinks and a heat sink according to the invention, respectively.

FIG. 9 is a schematic plan view similar to FIG. 4 illustrating the shape of rhombic pin fins.

FIG. 10 is a schematic plan view similar to FIG. 4 illustrating the shape of crescent moon shaped pin fins.

FIG. 11 is a schematic plan view of flow patterns between crescent moon pin fins with a concave-convex pin fin arrangement.

FIG. 12 is a schematic plan view of flow patterns between crescent moon pin fins with a concave-concave and convex-convex pin fin arrangement.

### DETAILED DESCRIPTION OF PREFERRED EMBODIMENTS

In the following a detailed description of preferred embodiments of the present invention will be given.

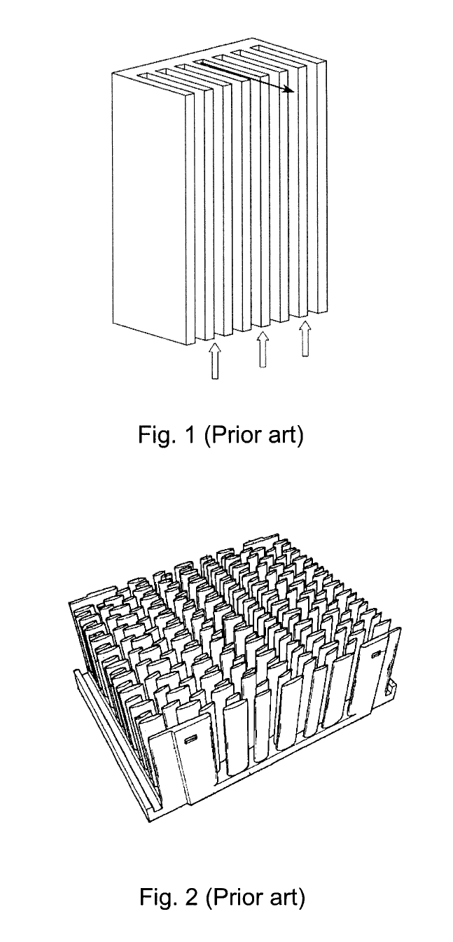

The prior art heat sinks disclosed in FIGS. 1 and 2 have been discussed in the background section and will not be further discussed herein.

According to the geometric relationship of the base normal line and the cooling flow direction, two types of heat sinks can be identified: 1) When the cooling flow direction parallel to the base normal line, the heat transfer mode is mainly natural convection. This type of heat sinks is usually orientated horizontally. 2) When the flow direction is perpendicular to the normal line of the heat sink base, either natural convection or forced convection can be applied to the heat sink. This type of heat sinks is usually oriented vertically. The present invention is primarily applied to the second case, i.e., the flow direction is perpendicular to the normal line of the heat sink base.

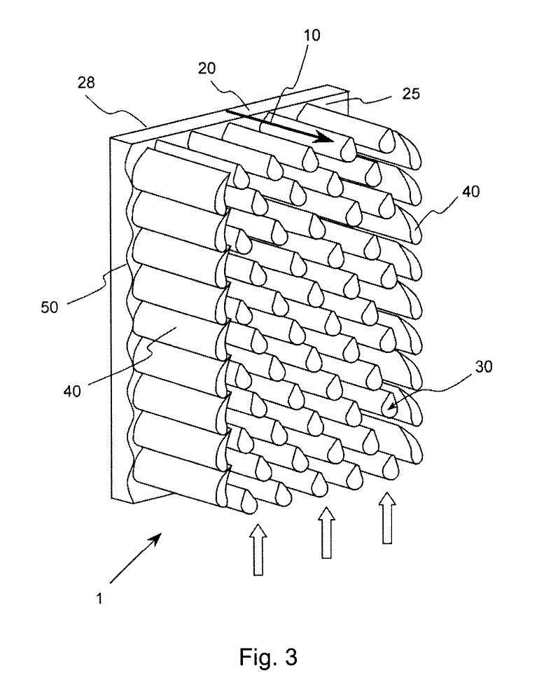

FIG. 3 presents a heat sink according to the present invention, generally referenced 1, with an array of raindrop-shaped pin fins 30. The pin fins are preferably protruded in the direction of a normal vector 10 of a bottom surface 28 from a top surface 25 of a heat sink base panel 20 and are arranged in staggered rows. An electronic component (i.e., heat generation unit, not shown) is coupled to the heat sink at the bottom surface 28 of the base panel 20 thereof. Thus, the heat sink base 20 acts as the primary conduction path and the pin fins 30 act as convection path for heat generated by electronic component.

Air guide pin fins 40 enclose the pin fins 30 on two sides of the heat sink 1 for maximizing the cooling flow rate and consequently enhancing the heat dissipation from the heat sink 1. As a matter of fact, in such an arrangement of the air guide pin fins, cooling air can easily enter into the heat sink but hardly leak out from the heat sink. The general cooling flow direction is indicated by the arrows.

Heat transfer enhancement may be provided by forming the top surface 25 with a defined wavy, preferably sinusoidal profile 50 in the cooling flow direction, as illustrated in FIG. 3. As will be understood, with such a wavy profile surface, the cooling flow changes it flowing direction periodically along the flow path, causing local flow separation and reattachment with the base top surface 25. Such disturbances between the flow and walls reduces thermal boundary layer thickness and, as a result, increases surface heat transfer coefficient.

The heat sink 1 may be fabricated by a variety of manufacturing methods such as casting, machining, welding, etc. using a material of copper or aluminum alloys or other suitable thermally conductive material.

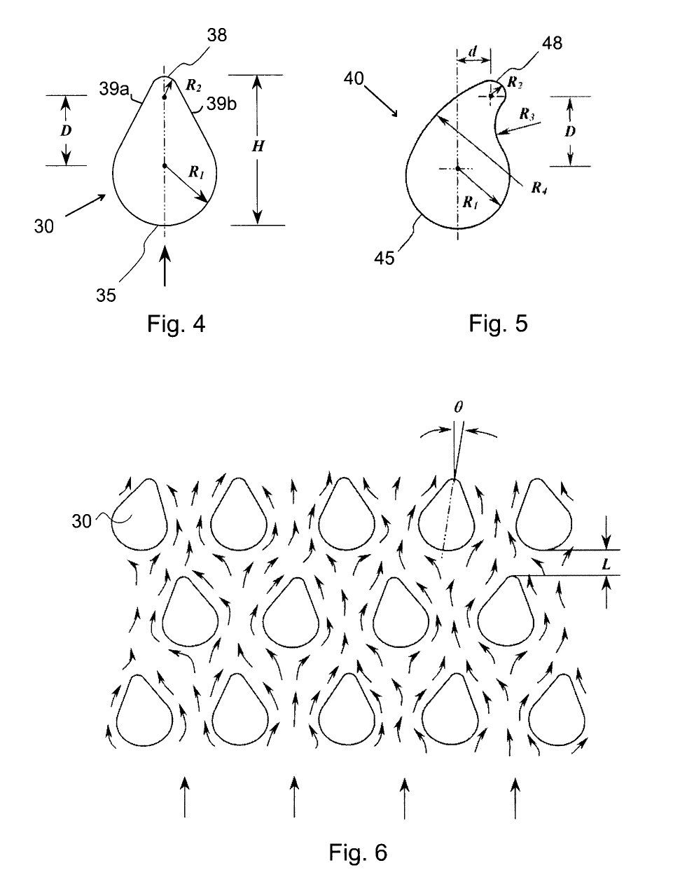

FIG. 4 illustrates the cross-sectional shape of one of the raindrop-shaped pin fins 30, wherein the general flow direction is indicted by a vertically oriented arrow. The cross-section of the pin fin has a large rounded end 35 with a first radius of R₁ at the flow upstream and a small rounded end 38 with a second radius R₂ at the flow downstream. Straight portions 39a, 39b interconnect the two radii. The distance between the radius center points for the first and second radii is denoted D in the figure and the total length or, in vertical orientation of the heat sink, the fin height is denoted H.

The heat sink 1 with the raindrop-shaped pin fins is so designed as to minimize the wake at the tail of the fin and correspondingly, to minimize the heat sink pressure drop. It can be seen in FIG. 4 that the primary difference between a raindrop-shaped fin and an elliptical fin is the shape at the fin leading edge with respect to the cooling flow. The raindrop-shaped fin shown in FIG. 4 has the first radius of R₁. Along the fin axis, the fin dimension changes sharply to the small second radius of R₂. This structure with one large and one small radius can significantly reduce the drag force generated at the tail of the fin and consequently reduce the pressure drop across the fin. Thus, a raindrop-shaped pin fin is characterized by three dimensions: the leading first radius R₁, the trailing second radius R₂, and the fin height H or alternatively the distance D. Thus, the raindrop shaped pin fins can be characterized by introducing a fin ratio ε, where ε=R₁/H and 0<ε<1. It can be seen that when ε approaches unit, R₁=H, the fin shape approaches a semi-sphere; when ε approaches zero, H becomes infinity long and the fin turns to a long plate. For the current applications, ε usually ranges from 0.2 to 0.5. Thus, with a fixed size of R₁ (for an example, R₁=1.5 mm), the thermal performance of the raindrop-shaped pin fin heat sink can be optimized by selecting the best ε value, according to the cooling flow velocity, the size of the heat source, the thermal boundary condition (e.g., uniform wall temperature and uniform heat flux) and the heat transfer modes, i.e., natural or forced convection.

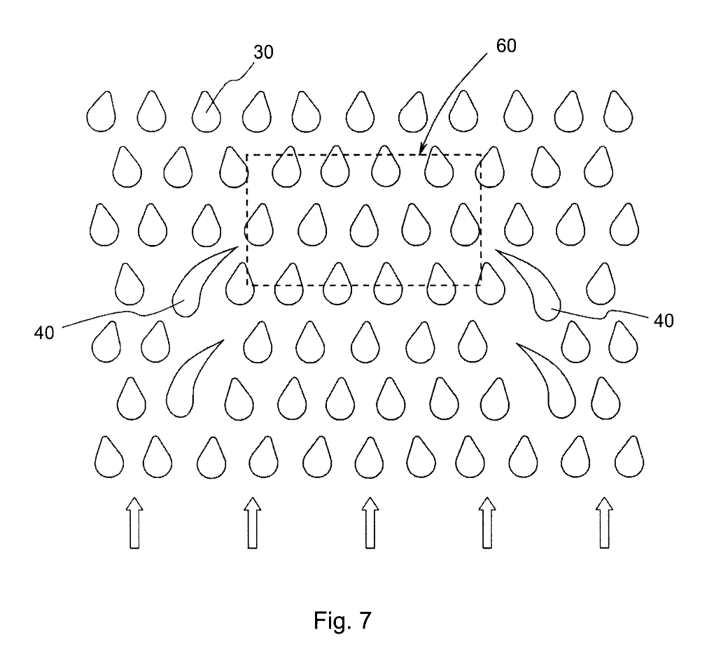

FIG. 5 shows the raindrop-shaped pin fin 40 with a bending tail. Comparing with the pin fin in FIG. 4, while the fin head which is formed by the front edge 45 remains unchanged, the fin tail which is formed by the back edge 48 shifts a distance normally to the flow direction. Thus, two lines having two more radiuses, i.e. R3 and R4, are used to smoothly join the curved front edge 45 (with R1) and back edge 48 (with R2). This type of pin fins can be used to control the cooling flow direction, as depicted in FIG. 7.

FIG. 6 depicts the flow pattern between raindrop-shaped pin fins 30. As cooling flow passes the pin fins, horseshoe vortices are generated in the stagnation area at the front edge 35 of the pin fin 30 by virtue of the staggered fin arrangement, and the flow separates around the pin fins. The horseshoe vortices will enhance the heat transport. The staggered arrangement of the pin fins increase the local turbulent level and reduces the size of the wakes, thus tending to reduce the local thermal boundary layer thickness and thus augment heat transport in these regions. As such, the pin fins serve as turbulence promoters to enhance heat transfer. The combination of the increased heat transfer coefficient and enlarged flow contact area considerably improves heat convection in the flow channel, thereby reducing or even eliminating hot spots.

The fin angle θ is defined as the angle between the fin symmetry line or centerline and the cooling flow direction. In FIG. 6, a symmetry line is shown with dash-dotted line. The angle θ of each pin fin may preferably vary between +20 and −20 degrees for maximizing the heat transfer rate. Thus, the symmetry lines of at least some of said plurality of pin fins are non-parallel with respect to one another.

For instance, the pins adjacent to the heat generation unit should point towards the heat generation unit at an appropriate angle to lead more cooling flows to the mounting area of the heat generation unit for enhancing heat transfer and improving the temperature distribution.

Another variable that can be used to maximize the heat transfer rate is the fin distance L between adjacent rows of pin fins. At the cooling flow upstream, because the temperature differential ΔT between the convective air and the heat sink is relative large, the fin density L can be large. As the temperature of cooling air increases along its path, ΔT becomes smaller and smaller. Thus, the fin density L may vary accordingly for achieving higher cooling flow velocity, and in turn, higher heat dissipation rate. In the preferred embodiment, the distance between adjacent rows of pin fins decreases along the cooling flow path.

There are several benefits of using raindrop-shaped pin fins. Firstly, the fins function as turbulent promoters to create local turbulence for enhancing heat transport. Secondly, the fins are designed to minimize the fin-induced wakes at the fin tails, whereby they provide the lowest resistance to the convective airflow. Thirdly, the local heat transfer can be easily controlled by varying the fin angle θ and the fin distance L. Fourthly, the local heat transfer can be alternatively controlled by changing the fin density and fin size along the cooling flow path.

As shown in FIG. 3 the air guide pin fins 40 are arranged at the two sides of the heat sink 1 for maximizing the cooling flow rate and thus, enhancing the heat dissipation from the heat sink 1. As shown in the embodiment in FIG. 7, the air guide pin fins 40 can be also applied inside a plurality of the raindrop-shaped pin fins 30 for leading the cooling flow directly to the heat generation unit. The mounting area of the heat generation unit, which is mounted on the bottom surface 28 of the base panel 20, is shown with dashed lines 60 in FIG. 7. An air guide pin fin has an approximately semi-sphere at its leading edge and a longer tail, bending to the heat generation unit.

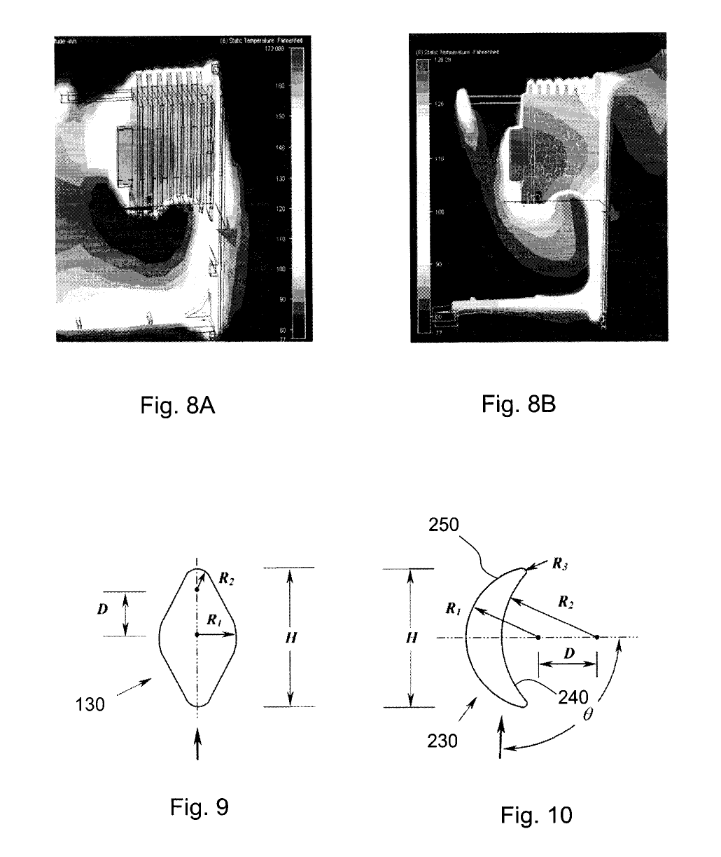

A computational fluid dynamics (CFD) model has been carried out to compare the thermal performance between the straight plate-fin heat sink and raindrop-shaped pin fin heat sink. In order to determine merely the impact of the pin fin shape on the heat dissipation, the air guide pin fins and wavy profile base are not included in the analysis models. As shown in FIG. 8A, under identical thermal conditions, with a prior art straight plate-fin heat sink the maximum temperature Tₘₐₓ=172.09 F (77.83° C.) whereas as shown in FIG. 8B the heat sink according to the invention results in a maximum temperature of Tₘₐₓ=128.28 F (53.49° C.). Thus, the heat sink with raindrop-shaped pin fins can efficiently enhance the heat dissipation and improve the heat sink thermal performance about 10-30% due to not only the introduced local flow turbulent level but also the increased flow cross-sectional contact area.

An alternative cross-sectional shape of pin fins is illustrated in the exemplary embodiment shown in FIG. 9. In this embodiment, a pin fin 130 having rhombic cross-sectional shape performs the same purposes as previously explained for the embodiment shown in FIG. 4. Actually, this rhombic fin shape has the same profile at its tail to the raindrop-shape fins for minimizing wakes behind the pins. This design is suitable when a flow velocity is relative low, such as for natural convection cases.

Referring now to the embodiment hereof illustrated in FIG. 10, pin fins 230 with a “crescent moon” shape can also be used in a heat sink. Characterizing with a major axis, a crescent moon pin fins 230 consists of a concave surface 240 and a convex surface 250, with the corresponding radiuses R₂ and R₁, respectively. The center points of these two radiuses are located on the fin major line (i.e., the symmetric line).

This concavo-convex configuration of pin fins can augment the flow turbulence level and thus enhance convective heat transfer between cooling flow and pin fins by incorporating an airfoil design while maintaining large exposed surface area for heat transfer. The airfoil design in the shape of crescent moon is chosen appropriate radii R₁ and R₂ and H to reduce thermal boundary layer build-up. This type of fins is useful in changing the cooling flow direction and thus enhancing the flow turbulence level. For this case, the fin angle, which is defined as the angle between the fin centerline and the flow direction, ranges from 70 to 110 degrees.

Referring to the embodiment hereof illustrated in FIG. 11, crescent moon pin fins 230 are configured in a concave-convex pattern at fin rows. The orientation of pin fins between the adjacent rows is opposite. This configuration forces the cooling flow to change its flow direction periodically as it makes its way through the pathway. This causes local flow separation disturbances and subsequent reattachment of flow in the fin boundary layer and correspondingly, increases the flow turbulence level and thus enhances convective heat transfer. In addition, the redeveloping boundary layer from the reattachment point also contributes to heat transfer enhancement.

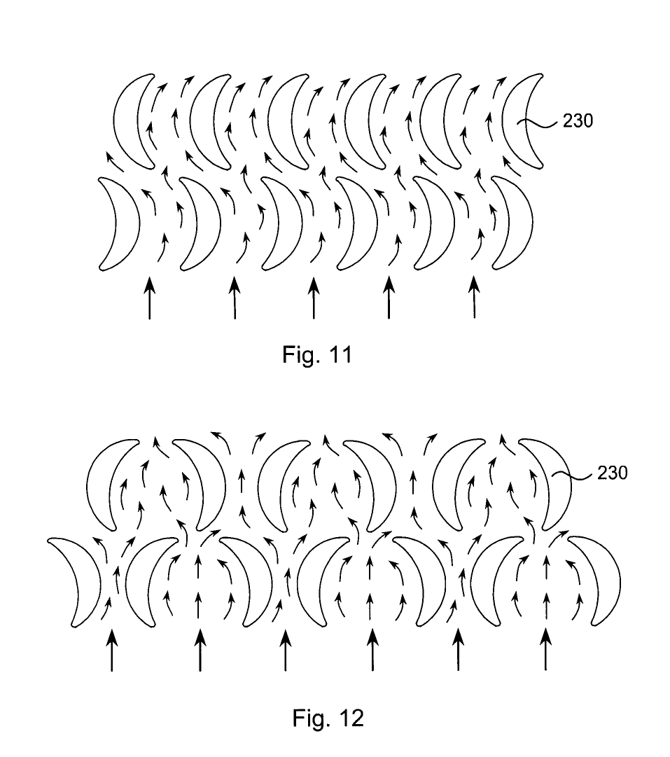

Referring now to the embodiment hereof illustrated in FIG. 12, crescent moon pin fins 230 are configured in a concave-concave and convex-convex pattern for all fin rows. This fin arrangement forms a large number of small convergent-divergent (convex-convex pattern) and divergent-convergent (concave-concave pattern) flow channels, configured in a staggered patter along the flow path. As a cooling flow passes convex-convex fin channels, the flow is compressed at the channel entrance and expanded at the channel exit. Contrarily, as the cooling flow passes concave-concave fin channels, the flow is expanded at the channel entrance and compressed at the channel exit. Thus, the variations in the flow velocity, flow direction, and local flow pressure will increase flow reactions and turbulence level in the flow field, resulting in the high heat transfer performance between the fins and cooling flow.

The present invention can replace the conventional straight plate-fin heat sink that has been used for more than a half century for cooling of electronic and electrical equipment. In particular, the present invention can be applied to all electronic and electrical devices with cooling channels using fluidic materials. It is important to note that the invented heat sink is not only used for natural convection applications, but also used for forced convection applications on that cooling flow is mainly generated from external devices such as fans.

Preferred embodiments of a heat sink according to the invention have been described. A person skilled in the art realizes that this could be varied within the scope of the appended claims. Thus, the pin fins of the inventive heat sink have been described and shown as arranged in staggered rows. However, alternative configurations are also possible, such as aligned pin fin arrays.

1. A heat sink comprising
a base panel having a top surface and a bottom surface;
a plurality of pin fins extending outwardly from a said top surface of said base panel;
each fin having a cross-sectional configuration with two radiuses, a first radius and a second radius, wherein the first radius is larger than the second radius;
wherein the first and second radiuses are tangentially interconnected by intermediate portions.

2. The heat sink according to claim 1, wherein the intermediate portions are essentially straight portions.

3. The heat sink according to claim 1, wherein the intermediate portions are curved portions.

4. The heat sink according to claim 1, wherein each fin has an essentially raindrop-shaped cross-sectional profile.

5. The heat sink according to claim 1, wherein the heat sink has a cooling flow direction, and wherein the first radius is provided on the upstream portion of the pin fin.

6. The heat sink according to claim 1, wherein the ratio between the first radius and the total length of the cross-sectional configuration of the fin is between 0.2 and 0.5.

7. The heat sink according to claim 1, wherein the pin fins protrude in the direction of the normal vector of the bottom surface.

8. The heat sink according to claim 1, wherein the pin fins are arranged in a plurality of spaced apart on said top surface of said base panel.

9. The heat sink according to claim 1, wherein the symmetry lines of at least some of said plurality of pin fins are non-parallel with respect to one another.

10. The heat sink according to claim 1, wherein the angle between the symmetry lines of pin fins and the cooling flow direction is between +20 and −20 degrees.

11. The heat sink according to claim 1, wherein the top surface of the base panel has a wavy profile along the cooling flow direction.

12. The heat sink according to claim 11, wherein the wavy profile has a sinusoidal contour.

13. The heat sink according to claim 1, wherein the distance between adjacent rows of pin fins varies along the cooling flow path.

14. The heat sink according to claim 1, wherein the fin density and fin size varies along the cooling flow path.

15. The heat sink according to claim 1, comprising a plurality of air guide pin fins extending outwardly from said top surface of said base panel, the air guide pin fins being arranged at the two sides of said heat sink.

16. The heat sink according to claim 1, comprising a plurality of air guide pin fins extending outwardly from said top surface of said base panel, the air guide pin fins being arranged inside said plurality of pin fins.

17. A heat sink comprising
a base panel having a top surface and a bottom surface;
a plurality of pin fins extending outwardly from a said top surface of said base panel;
each fin consisting essentially of crescent moon-shaped cross-sectional profile, primarily configuring with two radiuses,
wherein the center points of said two radiuses locating on the fin major axis.

18. The heat sink according to claim 17, wherein the pin fins protrude in the direction of the normal vector of the bottom surface.

19. The heat sink according to claim 17, wherein the pin fins arrange in concave-convex pattern.

20. The heat sink according to claim 17, wherein the pin fins arrange in concave-concave and convex-convex pattern.

21. The heat sink according to claim 17, wherein the angle between said symmetry lines of pin fins and the cooling flow direction is between 70 and 120 degrees.
